(19) United States
(12) Patent Application Publication
(10) Pub. No.: US 2007/0075339 A1
(43) Pub. Date: Apr. 5, 2007

(54) Gas-sensitive field effect transistor for detecting chlorine

(76) Inventors: Thorsten Knittel, Pentling (DE); Gunter Freitag, Munchen (DE); Ignaz Eisele, Icking (DE)

Correspondence Address: O'Shea Getz & Kosakowski, P.C., Suite 912, 1500 Main Street, Springfield, MA, 01115, US

(21) Appl. No.: 11/540,488

(22) Filed: Sep. 30, 2006

(30) Foreign Application Priority Data
Sep. 30, 2005 (DE) 10 2005 046 944.2

(51) Int. Cl. H01L 23/58

(52) U.S. Cl. 257/253

(57) ABSTRACT

A gas-sensitive field effect transistor reads signals generated by the principle of measuring work functions, for the detection of chlorine (Cl) with a gas-sensitive layer of gold.

### PRIORITY INFORMATION

This patent application claims priority from German patent application 10 2005 046 944.2 filed Sep. 30, 2005, which is hereby incorporated by reference.

### BACKGROUND OF THE INVENTION

This invention relates to the field of semiconductors and in particular to a gas sensor for detecting chlorine.

Due to the toxic and corrosive properties of chlorine, it is often desirable to detect this undesirable gas in ambient air. Known gas sensors for chlorine have typically been based on electrochemical cells that have a relatively short service life and a relatively high price, and that are also able to measure high concentrations only under certain conditions. Chlorine is a highly toxic gas that has a pungent odor. Values for the maximum workplace concentration (MWC) are 10 vpm with an instantaneous peak value of 20 vpm. Because of its low odor threshold and its piercing odor, chlorine is sensed at low concentrations, so that it can also be used as a guide gas for air quality in applications such as for example motor vehicle air conditioner systems.

Due to the importance in safety and the broad field of use of chlorine measurements, a number of different measurement systems are in use today, such as electrochemical cells. However, their cost is too high for many applications. In addition, sensor systems with electrochemical cells require a relatively high maintenance expense, and the service life of the individual sensors is relatively short.

Metal oxide sensors represent the lower price segment. Their reaction to a target gas is detected according to changes in conductivity. However, metal oxide sensors are operated at higher temperatures (e.g., above 200° C.) and therefore require high power to reach their nominal operating temperature. As a result metal oxide sensors are not suitable for many applications, such as battery-operated systems or for direct connection to a data bus.

The use of chlorine sensors is increasing due to regulatory requirements. Unfortunately, the relatively high costs involved in supplying sensors with the necessary operating energy and the like are significant drawbacks.

Gas sensors that measure a change of electron affinity or changes of their materials from interaction with gases to be detected can operate at low temperatures and thus with lower energy expenditure. The possibility is utilized of feeding into a field effect transistor (e.g., gas FET) the change of work function of gas-sensitive materials, and thereby measuring the change of work function as a change of current between the source and drain of the transistor. In essence, two transistors are used as so-called gas FETs. One transistor is the suspended gate field effect transistor (SGFET), and the other transistor is the capacitively coupled field effect transistor (CCFET). In both types, a suspended gate electrode is opposite the chip surface to form an air gap. In the SGFET, the channel region of the transistor is located on the side of the air gap opposite the gas-sensitive layer, and is separated from it by a suitable layer of insulation covering the channel region.

In the CCFET, the air gap is located between the gas-sensitive layer and an electrode opposite it that is capacitively coupled to the gas-sensitive layer. The electrode is conductively connected with the gate of the field effect transistor emitting the signal, and the field effect transistor can be separated spatially from the air gap. This electrode can be covered in the direction toward the air gap with a suitable layer of insulation.

The SGFET and the CCFET are both characterized by the hybrid design that is the basis of a relatively simple and reliable structural principle. Thus, the gas-sensitive gate (electrode) coated with the gas-sensitive layer on the one hand, and the actual transistor on the other hand, can be produced separately, and completion of construction by flip-chip technology, for example, permits joining the two elements with simultaneous precise mutual positioning. The ability to use various materials as the gas-sensitive layer is one advantage obtainable directly from this hybrid technique; these materials as a rule would not be combinable with the silicon components of a field effect transistor (e.g., because of the different nature of their composition). This applies particularly to metal oxides, which can be applied by thick film or thin film technology.

No materials have thus far been disclosed in the prior art by which a gas-sensitive field effect transistor can detect chlorine. Therefore, there is a need for a chlorine sensor that can be read by a FET.

### SUMMARY OF THE INVENTION

Briefly, according to an aspect of the present invention, a gas-sensitive field effect transistor includes a gas-sensitive layer of gold.

The present invention recognizes the advantages of gold as a gas-sensitive material for the detection of chlorine. Since gold in contact with chlorine forms gold chloride, and gold and gold chloride have different work functions, this reaction and thus the presence of extremely low chlorine concentrations may be determined with a gas-sensitive FET. Thus, the difference in work functions can be read using a gas sensor based on the field effect, and can be interpreted as a gas signal. An unheated sensor shows high sensitivity and high signal levels. However, the signal is irreversible.

The gas sensitive field effect transistor reads the work function on the gas-sensitive layer of gold. The gas-sensitive field effect transistor may have an operating temperature between room temperature and 200° C. Certain temperature variations or temperature increases may be necessary to allow reversible changes to occur. The relatively low operating temperature in combination with gas-sensitive layers of gold facilitates a realizable and commercially practical gas sensor. An unheated sensor shows high sensitivity and high signal levels. However, the signal is irreversible.

This sensor, operated at room temperature, is sensitive down to the high ppb (parts per billion) range. This variant of sensor can be used as a dosimetric sensor, and the display signal is then the chlorine dosage, or the cumulative product of the prevailing chlorine concentration multiplied by the time during which this chlorine concentration is present. After the measurement, the sensor may be reactivated by a brief period of heating at about 200° C. or above in order to reset the signal.

The sensor may be operated while heated. For example, when the sensor is constantly heated the signal is continuously reset, which advantageously leads to the sensor signal following the currently prevailing chlorine concentration. The sensitivity of the sensor is displaced toward lower concentrations of chlorine with increasing operating temperature.

Advantageously, the sensor is miniaturized, economical and has long-term stability, that is, the sensor does not have an inherent limitation of maximum service life to about two years. Because of the ability to operate this sensor as a dosimeter with no heating, it can also be operated in mobile applications with no heating energy requirement. The sensor may be used for monitoring compliance with maximum allowed limits with regard to air quality in occupied areas. Similarly, the gas sensitive field effect transistor may be used for detecting chlorine gas escaping into facilities that store, process, or contain chlorine gas, or whose operation can produce chlorine gas. In addition, the gas-sensitive field effect transistor may be used in networked systems for the detection of chlorine.

These and other objects, features and advantages of the present invention will become more apparent in light of the following detailed description of preferred embodiments thereof, as illustrated in the accompanying drawings.

### BRIEF DESCRIPTION OF THE DRAWINGS

FIG. 1 illustrates a gas FET for detecting chlorine;

FIG. 2 illustrates the chlorine gas load and signal of a gas-sensitive FET at room temperature;

FIG. 3 illustrates diagram similar to FIG. 2 with signals at 80° C.; and

FIG. 4 illustrates diagram similar to FIG. 2 with signals at 180° C.

### DETAILED DESCRIPTION OF THE INVENTION

The applications for chlorine sensors are numerous; many current problems can be solved by the use of gas FETs, for example in the fields of motor vehicle air conditioning systems, interior air quality monitors, battery operation of equipment, in particular mobile equipment, for example as a personal portable dosimeter for workplace safety, and networked systems that organize gas sensors through data bus lines. The mode of operation of gas sensors based on FETs is generally known.

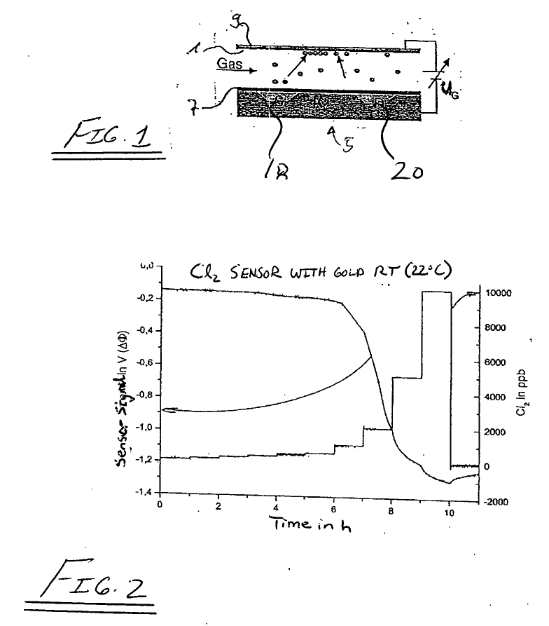

FIG. 1 illustrates a gas sensor with suspended gate (SGFET) with a sensitive layer 1 applied to a gate electrode 9. Gate insulation 7 belongs to the basic transistor structure that includes the transistor channel 5 and the adjacent source 18 and drain 20. The voltage U_{G} is the gate voltage that is developed in connection with a sensor signal. The sensitive layer 1 comprises gold.

FIG. 2 shows the measurement of the functionality of a gas-sensitive field effect transistor with a gas-sensitive layer of gold. These diagrams show the measurement signals recorded at room temperature, at 22° C. for example. The functioning mode is based on the reaction of the gold in the presence of chlorine to provide gold chloride. This reaction can be reversed at about 200° C. If the sensor is operated at room temperature, the corresponding operating mode has to provide an interim regeneration phase switched in with brief heating to about 200° C. If the sensor is operated at about 150-180° C., for example, then it is a reversible, continuously functioning sensor with an acceptable time constant. Reversibility can be achieved even at about 80° C.

The ratio between gold and gold chloride is reached as a function of the gas concentration, and can be determined with the gas FET.

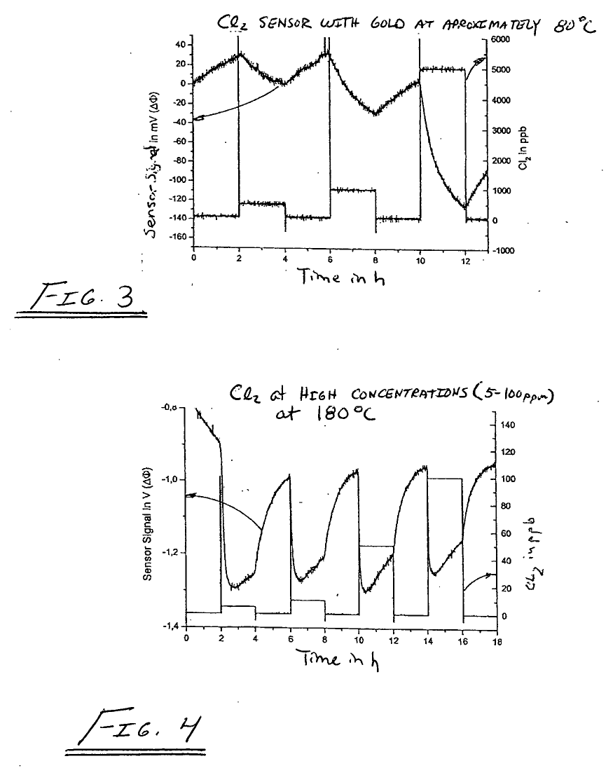

FIG. 3 illustrates a plot of a sensor signal is recorded at an operating temperature of 80° C. The signals are already reversible, but the time constants are still high.

FIG. 4 illustrates a plot of sensor signals recorded at an operating temperature of 180° C. The sensor is reversible. Concentrations greater than 5 ppm can no longer be resolved. However, the sensor is best suited for low chlorine concentrations.

Cathode sputtering, vacuum metallization methods, screen printing methods, and CVD methods may be used to prepare the gas-sensitive gold layers. Typical layer thicknesses are in the range between 10 nm and 10 μm. The use of a porous open-pored layer is especially advantageous. The preparation of gold or gold-containing materials in a gas sensor for chlorine detection extends the palette of materials for gas-sensitive layers that are used in gas-sensitive field effect transistors. It is sometimes necessary to heat the layer, so that it is possible to return to an original value after gas exposure. Operating the sensor at room temperature shows integrating behavior, with the reaction in the field effect transistor being reversible beyond 80° C.; however, the time constant is still relatively large. The signal level is generally reduced at higher temperatures.

Advantageously, the gas-sensitive GET for detecting chlorine of the present invention includes the features of low energy consumption; a small geometric size that facilitates the realization of sensor systems; monolithic integration of the electronics into the sensor chip; and the use of mature, economical semiconductor manufacturing techniques for making the gas FET.

Although the present invention has been illustrated and described with respect to several preferred embodiments thereof, various changes, omissions and additions to the form and detail thereof, may be made therein, without departing from the spirit and scope of the invention.

What is claimed is:

1. A gas-sensitive field effect transistor comprising a gas sensitive layer of gold for detecting chlorine.

2. The gas-sensitive field effect transistor of claim 1, where the field effect transistor comprises suspended gate FET.

3. The gas-sensitive field effect transistor of claim 1, where the field effect transistor comprises a capacitively coupled FET.

4. The gas-sensitive field effect transistor of claim 1, where the gas-sensitive layer is between 10 nm and 10 μm.

5. The gas-sensitive field effect transistor of claim 1, where the operating temperature of the gas-sensitive layer is adjustable by an electric heater.

6. The gas-sensitive field effect transistor of claim 1, further comprising a battery that provides power to the gas-sensitive field effect transistor.

7. The gas-sensitive field effect transistor of claim 1, wherein the gas-sensitive field effect transistor is co-located on a semiconductor with a circuit that pre-processes, analyzes, and passes along the signals of the gas-sensitive field effect transistor.

8. A method for operating a gas-sensitive field effect transistor, comprising providing a gas-sensitive layer of gold.

9. The method of claim 8, further comprising intermittently heating the gas-sensitive field effect transistor to about 200° C. for regeneration.
